(19) United States
(12) Patent Application Publication
(10) Pub. No.: US 2007/0164404 A1
(43) Pub. Date: Jul. 19, 2007

(54) Semiconductor package

(75) Inventor: Kyu-Jin Han, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/653,249

(22) Filed: Jan. 16, 2007

(30) Foreign Application Priority Data
Jan. 17, 2006 (KR) 10-2006-004700

(51) Int. Cl. H01L 23/495

(52) U.S. Cl. 257/666

(57) ABSTRACT

A semiconductor package may include a semiconductor chip assembly, a signal input/output member and an encapsulating member. The semiconductor chip assembly may include first pads and second pads. The first pads may be exposed in a first direction. The second pads may be exposed in a second direction substantially opposite to the first direction. The signal input/output member may include first terminals and second terminals. The first terminals may be electrically connected to the first pads. The second terminals may be electrically connected to the second pads. The encapsulating member may encapsulate the semiconductor chip assembly.

### PRIORITY STATEMENT

This application claims priority under 35 U.S.C. § 119 to Korean Patent Application No. 10-2006-0004700 filed on Jan. 17, 2006, in the Korean Intellectual Property Office, the entire contents of which are incorporated herein by reference.

### BACKGROUND

1. Field

Example embodiments relate to a semiconductor package. More particularly, example embodiments relate to a semiconductor package that may reduce thermal shock and/or mechanical damage that may occur during a package process, for example.

2. Description of the Related Art

A semiconductor package may be employed to electrically connect a semiconductor chip to an external device. In addition, the semiconductor package may reduce mechanical and/or thermal damage to the semiconductor chip manufactured by a semiconductor manufacturing processes.

The semiconductor chip may be provided on a die pad of a lead frame to be electrically connected to the external device. Here, a bonding pad formed at the semiconductor chip may be electrically connected to a lead of the lead frame by a conductive member. The bonding pads and the leads may be electrically connected to each other by a conductive wire.

The semiconductor chip, the lead frame and the conductive wire may be encapsulated using a resin to reduce the mechanical and/or thermal damage to the semiconductor chip. The resin may include an epoxy resin, for example. The resin may include a silica bead having a diameter in a range of tens to hundreds of micro meters.

The semiconductor chip and the lead frame may be provided inside a mold having a cavity. A melted resin may be provided inside the cavity so that the semiconductor chip, some of the lead frames and the conductive wire may be encapsulated.

In this case, the silica bead in the melted resin may scratch the semiconductor chip while encapsulating the semiconductor chip. Thus, a surface of the semiconductor chip may be damaged. In addition, the semiconductor chip may be damaged by heat applied to the surface of the semiconductor chip while packaging the semiconductor chip.

### SUMMARY

Example embodiments may provide a semiconductor package capable of improving reliability by reducing mechanical and/or thermal damage, for example.

Example embodiments of a semiconductor package may include a semiconductor chip assembly, a signal input/output member and an encapsulating member. The semiconductor chip assembly may have first pads and second pads. The first pads may be exposed in a first direction. The second pads may be exposed in a second direction opposite to the first direction. The first and second pads may face in opposite directions.

The signal input/output member may have first terminals and second terminals. The first terminals may be electrically connected to the first pads. The second terminal may be electrically connected to the second pads. By way of example only, the signal input/output member may be a lead frame (or a printed circuit board) combined with the semiconductor chip assembly.

The encapsulating member may encapsulate the semiconductor chip assembly. The encapsulating member may absorb external shock and/or vibration so that damage to the semiconductor chip assembly may be reduced.

### BRIEF DESCRIPTION OF THE DRAWINGS

Example embodiments will be understood from the following detailed description taken in conjunction with the accompanying drawings.

FIG. 1 is a perspective view illustrating a semiconductor chip assembly of a semiconductor package in accordance with an example embodiment.

FIG. 2 is a cross-sectional view taken along a line 2-2 in FIG. 1.

FIG. 3 is a perspective view illustrating a semiconductor chip assembly of a semiconductor package in accordance with an example embodiment.

FIG. 4 is a cross-sectional view taken along a line 4-4 in FIG. 3.

FIG. 5 is a cross-sectional view taken along a line 5-5 in FIG. 3.

FIG. 6 is a cross-sectional view illustrating a signal input/output member of a semiconductor package in accordance with an example embodiment.

FIG. 7 is a cross-sectional view illustrating a semiconductor chip assembly combined with a signal input/output member in accordance with an example embodiment.

FIG. 8 is a cross-sectional view illustrating a bonding of a conductive wire to a semiconductor chip assembly in accordance with an example embodiment.

FIG. 9 is a cross-sectional view illustrating an encapsulating member encapsulating a semiconductor chip assembly and a signal input/output member in FIG. 8.

FIG. 10 is a cross-sectional view illustrating a semiconductor chip assembly and a signal input/output member of a semiconductor package in accordance with an example embodiment.

FIG. 11 is a plan view illustrating a first face in FIG. 10.

FIG. 12 is a plan view illustrating a second face in FIG. 10.

FIG. 13 is a cross-sectional view illustrating a conductive member assembling a signal input/output member and a semiconductor chip assembly in FIG. 10.

FIG. 14 is a cross-sectional view illustrating a semiconductor package in accordance with an example embodiment.

FIG. 15 is a cross-sectional view illustrating a semiconductor chip assembly and a signal input/output member of a semiconductor package in accordance with an example embodiment.

FIG. 16 is a plan view illustrating a first face of the signal input/output member in FIG. 15.

FIG. 17 is a plan view illustrating a second face of the signal input/output member in FIG. 15.

FIG. 18 is a cross-sectional view illustrating a semiconductor package in accordance with an example embodiment.

### DESCRIPTION OF EXAMPLE NON-LIMITING EMBODIMENTS

Example embodiments will be described with reference to the accompanying drawings. Example embodiments may, however, be embodied in many different forms and should not be construed as limited to the embodiments set forth herein. Rather, the embodiments are provided so that the teachings in this disclosure will be thorough and complete, and will fully convey the scope of example embodiments to those skilled in the art. The principles and features of example embodiments may be employed in varied and numerous embodiments without departing from the spirit and scope of the teachings herein. In the drawings, the size and relative sizes of layers and regions may be exaggerated for clarity. The drawings are not to scale. Like reference numerals designate like elements throughout the drawings.

It will be understood that when an element or layer is referred to as being “on,” “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, no intervening elements or layers are present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of example embodiments.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

The terminology used herein is for the purpose of describing particular embodiments only and is not intended to be limiting of the example embodiments. As used herein, the singular terms “a,” “an” and “the” are intended to include the plural forms as well, unless the context clearly indicates otherwise. It will be understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of this specification and the relevant art and will not be interpreted in an idealized and/or overly formal sense unless expressly so defined herein.

Example embodiments are described with reference to cross-section illustrations that are schematic illustrations of idealized embodiments. As such, variations from the shapes of the illustrations as a result, for example, of manufacturing techniques and/or tolerances, may be expected. Thus, example embodiments should not be construed as limited to the particular shapes of regions illustrated herein but are to include deviations in shapes that result, for example, from manufacturing. For example, a region illustrated as a rectangle will, typically, have rounded and/or curved features. Thus, the regions illustrated in the figures are schematic in nature of a device and are not intended to limit the scope of example embodiments.

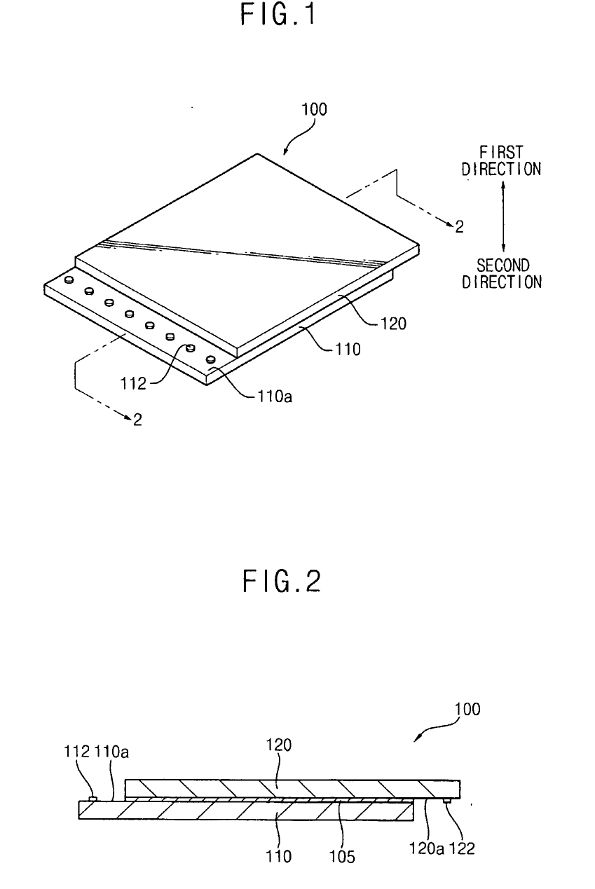

FIG. 1 is a perspective view illustrating a semiconductor chip assembly of a semiconductor package in accordance with an example embodiment.

FIG. 2 is a cross-sectional view taken along a line 2-2 in FIG. 1.

Referring to FIGS. 1 and 2, a semiconductor chip assembly 100 of a semiconductor package may include a first semiconductor chip 110 and a second semiconductor chip 120.

The first semiconductor chip 110 may include first pads 112. The first pads 112 may be arranged along an edge of an active face 110a of the first semiconductor chip 110. By way of example only, the first pads 112 may be arranged in a substantial line shape. Alternatively, the first pads 112 may be arranged in a substantial zigzag shape, or some other alternative shape.

Referring to FIG. 2, the second semiconductor chip 120 may include second pads 122. The second pads 122 may be arranged along an edge of an active face 120a of the second semiconductor chip 120. By way of example only, the second pads 122 may be arranged in a substantial line shape. Alternatively, the second pads 122 may be arranged in a substantial zigzag shape, or some other alternative shape.

The active face 110a of the first semiconductor chip 110 may face the active face 120a of the second semiconductor chip 120.

An adhesion member 105 may be provided between the active face 110a of the first semiconductor chip 110 and the active face 120a of the second semiconductor chip 120. The adhesion member 105 may attach the second semiconductor chip 120 to the first semiconductor chip 110.

The first and second semiconductor chips 110 and 120 may be assembled together so that the first pads 112 may not be overlapped by the second semiconductor chip 120. Thus, the first pads 112 protruding in a first direction may be exposed from the second semiconductor chip 120. In addition, the second pads 122 protruding in a second direction substantially opposite to the first direction may be exposed from the first semiconductor chip 110.

By way of example only, the first pads 112 of the first semiconductor chip 110 and the second pads 122 of the second semiconductor chip 120 may be arranged substantially in parallel with each other.

As described above, the active face 110a of the first semiconductor chip 110 from which the first pads protrude and the active face 120a of the second semiconductor chip 120 from which the second pads protrude may face each other. Thus, the first and second semiconductor chips 110 and 120 may be protected from thermal and/or mechanical damage when the semiconductor package is manufactured. For example, the active faces of the first and second semiconductor chips 110 and 120 may be shielded from scratches that may otherwise occur during manufacture of the semiconductor package.

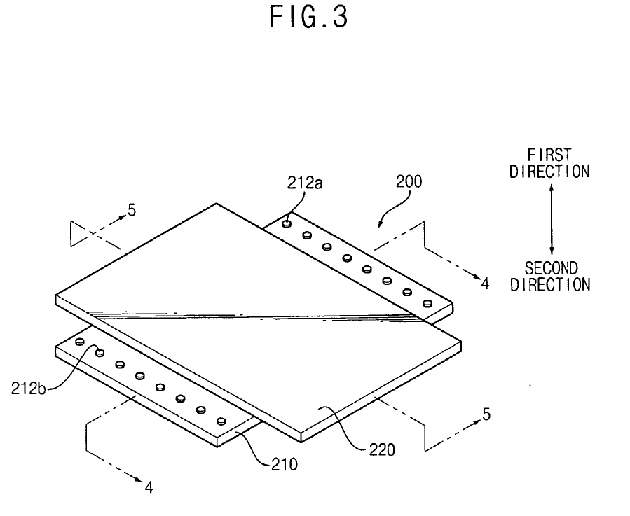

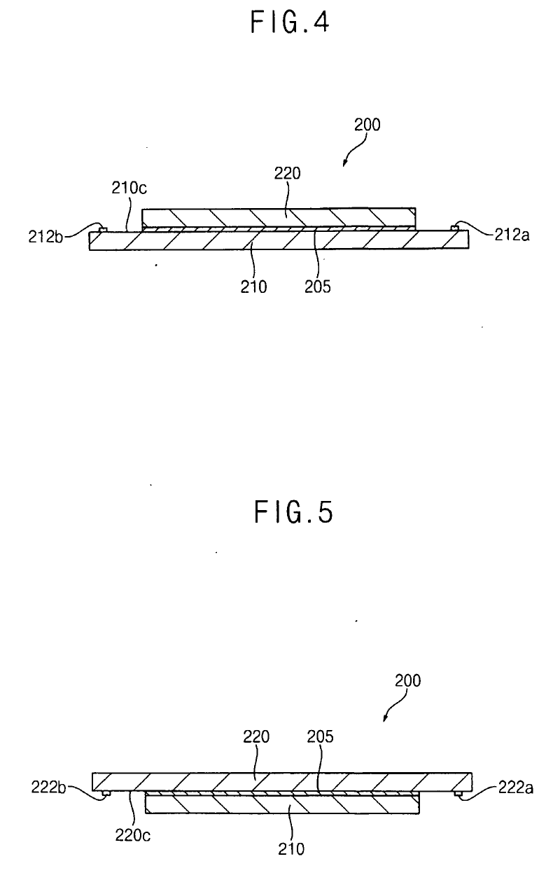

FIG. 3 is a perspective view illustrating a semiconductor chip assembly of a semiconductor package in accordance with an example embodiment. FIG. 4 is a cross-sectional view taken along a line 4-4 in FIG. 3. FIG. 5 is a cross-sectional view taken along a line 5-5 in FIG. 3.

Referring to FIG. 3, a semiconductor chip assembly 200 of a semiconductor package may include a first semiconductor chip 210 and a second semiconductor chip 220.

Referring to FIG. 4, the first semiconductor chip 210 may include first pads 212a and 212b. The first pads 212a and 212b may be arranged along both edges of an active face 210c of the first semiconductor chip 210. By way of example only, the first pads 212a and 212b may be arranged in a substantial line shape. Alternatively, the first pads 212a and 212b may be arranged in a substantial zigzag shape, or some other alternative shape.

Referring to FIG. 5, the second semiconductor chip 220 may include second pads 222a and 222b. The second pads 222a and 222b may be arranged along both edges of an active face 220c of the second semiconductor chip 220. By way of example only, the second pads 222a and 222b may be arranged in a substantial line shape. Alternatively, the second pads 222a and 222b may be arranged in a substantial zigzag shape, or some other alternative shape.

An adhesion member 205 may be provided between the active face 210c of the first semiconductor chip 210 and the active face 220c of the second semiconductor chip 220. The adhesion member 205 may attach the second semiconductor chip 220 to the first semiconductor chip 210. Here, the first pads 212a and 212b of the first semiconductor chip 210 may not be overlapped with the second semiconductor chip 220. Thus, the first pads 212a and 212b protruding in a first direction may be exposed from the second semiconductor chip 220. In addition, the second pads 222a and 222b protruding in a second direction substantially opposite to the first direction may be exposed from the first semiconductor chip 210.

By way of example only, the first pads 212a and 212b may be arranged substantially perpendicular to the second pads 222a and 222b.

As described above, the active face 210c of the first semiconductor chip 210 and the active face 220c of the second semiconductor chip 220 may face each other. Thus, the first and second semiconductor chips 210 and 220 may be protected from thermal and/or mechanical damaged in manufacturing the semiconductor package. For example, the active faces 210c and 220c may be shielded from scratches that may otherwise occur during manufacture of the semiconductor package.

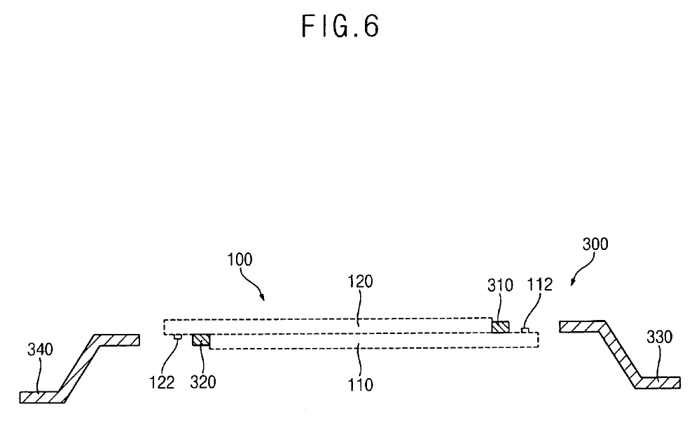

FIG. 6 is a cross-sectional view illustrating a signal input/output member of a semiconductor package.

Referring to FIG. 6, the signal input/output member 300 may include a first die pad 310, a second die pad 320, first leads 330 and second leads 340.

By way of example only, the first die pad 310 of the signal input/output member 300 may have a substantial bar shape, and the second die pad 320 of the signal input/output member 300 may have a substantial bar shape. The first die pad 310 may be parallel to the second die pad 320. The first die pad 310 may be spaced apart from the second die pad 320.

The first leads 330 may be adjacent to the first die pad 310. The number of first leads 330 may be the same as that of first pads 112 of the semiconductor chip assembly 100 in FIG. 1. In alternative embodiments, the number of first leads 330 may be different than the number of first pads 112.

The second leads 340 may be adjacent to the second die pad 320. The number of second leads 340 may be the same as that of second pads 122 of the semiconductor chip assembly 100 in FIG. 1. In alternative embodiments, the number of second leads 340 may be different than the number of second pads 122.

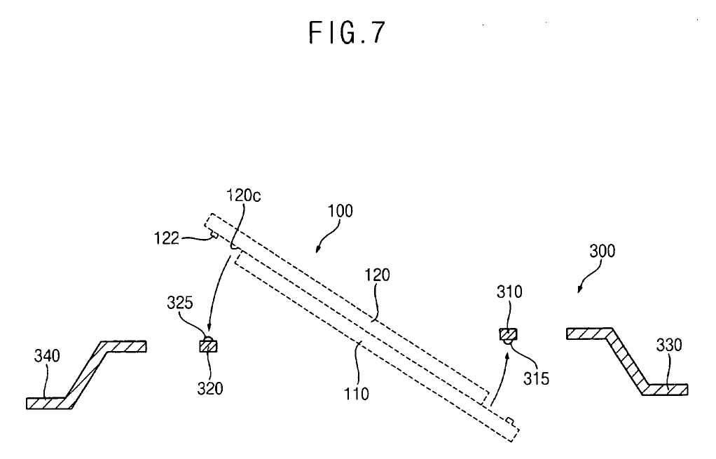

FIG. 7 is a cross-sectional view illustrating a semiconductor chip assembly 100 combined with a signal input/output member 300 in accordance with an example embodiment.

Referring to FIG. 7, the active face 110c of the first semiconductor chip 110 included in the semiconductor chip assembly 100 in FIG. 1 may be provided under a lower face of the first die pad 310. An adhesion member 315 may be provided on the lower face of the first die pad 310. The adhesion member 315 may attach the first die pad 310 to the active face 110c of the first semiconductor chip 110.

In addition, the active face 120c of the second semiconductor chip 120 included in the semiconductor chip assembly 100 in FIG. 1 may be provided over an upper face of the second die pad 320. An adhesion member 325 may be provided on the upper face of the second die pad 320. The adhesion member 325 may attach the second die pad 320 to the active face 120c of the second semiconductor chip 120.

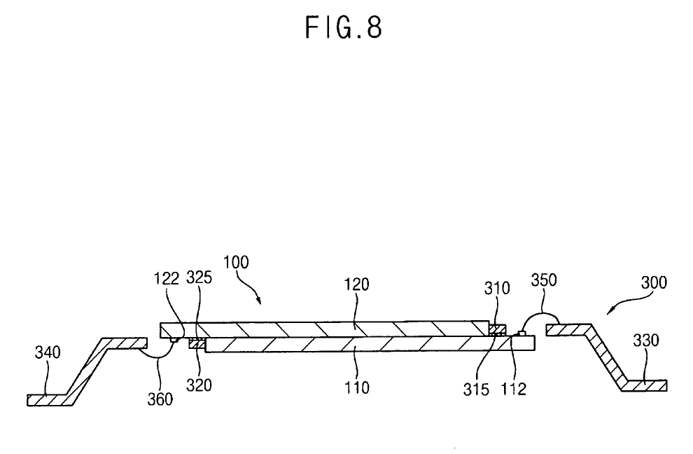

FIG. 8 is a cross-sectional view illustrating a bonding of a conductive wire to a semiconductor chip assembly 100 in accordance with an example embodiment.

Referring to FIG. 8, a conductive wire 350 may connect a first pad 112 of a first semiconductor chip 110 included in a semiconductor chip assembly 100 to an upper face of a first lead 330 included in a signal input/output member 300. By way of example only, the conductive wire 350 may include gold and/or silver.

A conductive wire 360 may connect a second pad 122 of a second semiconductor chip 120 included in a semiconductor chip assembly 100 to a lower face of a second lead 340 included in the signal input/output member 300. By way of example only, the conductive wire 350 may include gold and/or silver.

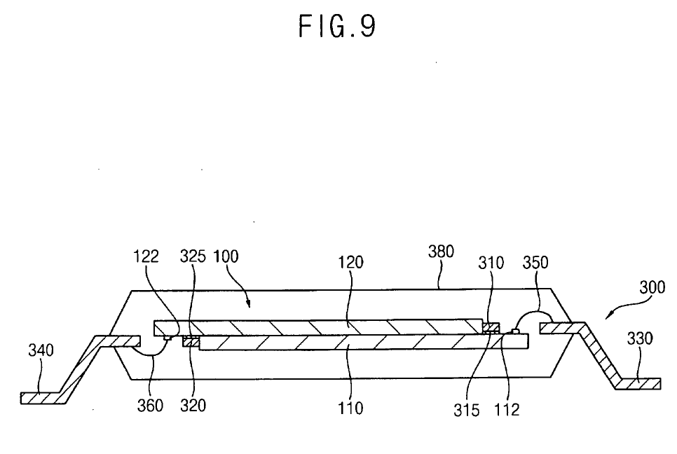

FIG. 9 is a cross-sectional view illustrating an encapsulating member encapsulating a semiconductor chip assembly 100 and a signal input/output member 300 in FIG. 8.

Referring to FIG. 9, the semiconductor chip assembly 100 and the signal input/output member 300 may be encapsulated with a melted encapsulation resin. Thus, an encapsulating member 380 may be formed.

Particularly, the semiconductor chip assembly 100 and the signal input/output member 300, which may be electrically connected to each other, may be disposed into a cavity (not shown) included in a mold (not shown). A melted encapsulation resin may be introduced into the cavity to encapsulate the semiconductor chip assembly 100 and the signal input/output member 300. Thus, an encapsulating member 380 may be formed.

The active face of the first semiconductor chip 110 included in the semiconductor chip assembly 100 may face the active face of the second semiconductor chip 120. In this way, scratches in the active faces of the first and second semiconductor chips 110 and 120 due to a silica grain in the encapsulation resin may be reduced. In addition, a generation of a thermal shock of the first and second semiconductor chips 110 and 120 due to a heat provided from the melted encapsulation resin may be reduced.

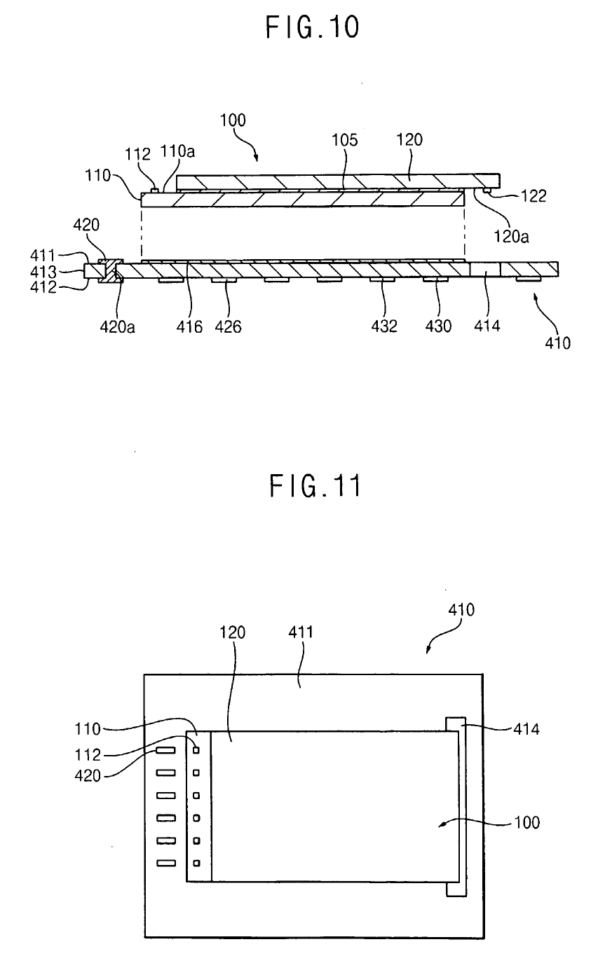

FIG. 10 is a cross-sectional view illustrating a semiconductor chip assembly and a signal input/output member of a semiconductor package in accordance with an example embodiment. FIG. 11 is a plan view illustrating a first face 411 in FIG. 10.

Referring to FIGS. 10 and 11, a semiconductor chip assembly 100 of a semiconductor package may include a first semiconductor chip 110 and a second semiconductor chip 120. The first semiconductor chip 110 may include first pads 112. The first pads 112 may be arranged along an edge of an active face 110a of the first semiconductor chip 110. By way of example only, the first pads 112 may be arranged in a substantial line shape. Alternatively, the first pads 112 may be arranged in a substantial zigzag shape, or some other alternative shape.

The second semiconductor chip 120 may include second pads 122. The second pads 122 may be arranged along an edge of an active face 120a of the second semiconductor chip 120. By way of example only, the second pads 122 may be arranged in a substantial line shape. Alternatively, the second pads 122 may be arranged in a substantial zigzag shape, or some other alternative shape.

An adhesion member 105 may be provided between the active face 110a of the first semiconductor chip 110 and the active face 120a of the second semiconductor chip 120. The adhesion member 105 may attach the second semiconductor chip 120 to the first semiconductor chip 110. Here, the first pads 112 of the first semiconductor chip 110 may not be overlapped with the second semiconductor chip 120. Thus, the first pads 112 protruding in a first direction may be exposed from the second semiconductor chip 120. In addition, the second pads 122 protruding in a second direction substantially opposite to the first direction may be exposed from the first semiconductor chip 110.

By way of example only, the first pads 112 of the first semiconductor chip 110 and the second pads 122 of the second semiconductor chip 120 may be arranged substantially parallel to each other.

As described above, the active face 110a of the first semiconductor chip 110 from which the first pads 112 protrude and the active face 120a of the second semiconductor chip 120 from which the second pads 122 protrude may face each other. Thus, the active faces of the first and second semiconductor chips 110 and 120 may be protected from thermal and/or mechanical damage during manufacture of the semiconductor package. For example, the active faces of the first and second semiconductor chips 110 and 120 may be shielded from scratches when the semiconductor package is manufactured.

A signal input/output member 410 may have a quadrilateral plate shape, for example. The signal input/output member 410 may include a first face 411, a second face 412, a side face 413 and an opening 414. The second face 412 may be substantially opposite to the first face 411. The side face 413 may be connected between the first face 411 and the second face 412. The opening 414 may be formed through the signal input/output member 410.

The semiconductor chip assembly 100 in FIG. 2 may be provided on the first face 411. For example, a first semiconductor chip 110 of the semiconductor chip assembly 100 may be provided on the first face 411. An adhesion member 416 may be provided between the first semiconductor chip 110 and the first face 411. The adhesion member 416 may attach the first semiconductor chip 110 to the first face 411. First terminals 420 may be provided on the first face 411. The first terminals 420 may correspond with the first pads 112 protruding from the first semiconductor chip 110 of the semiconductor chip assembly 100. The number of first terminals 420 may be the same as that of first pads 112. In alternative embodiments, the number of the first terminals 420 may be different than the number of the first pads 112.

Some of the first terminals 420 may extend to the second face 412 through the signal input/output member 410 by via patterns 420a.

FIG. 12 is a plan view illustrating a second face 412 in FIG. 10.

Referring to FIG. 12, second pads 122 of a second semiconductor chip 120 may correspond to an opening 414 formed through the signal input/output member 410.

Second terminals 430 may protrude from the second face 412 of the signal input/output member 410. The second terminals 430 may correspond to the second pads 122 exposed through the opening 414. The number of second terminals 430 may be the same as that of the second pads 122. In alternative embodiments, the number of second terminals 430 may be different than the number of second pads 122.

The signal input/output member 410 may include a first land pattern 426 and a second land pattern 432. The first land pattern 426 and the second land pattern 432 may protrude from the second face 412.

The first land pattern 426 may be electrically connected to the via pattern 420a of the first terminals 420. The first land pattern 426 may include a conductive portion 426a and a land portion 426b. The conductive portion 426a may have a substantial line shape. The conductive portion 426a may be electrically connected to the via pattern 420a. The land portion 426b may be electrically connected to the conductive portion 426a. The land portion 426b may have a substantial plate shape.

The second land pattern 432 may be electrically connected to the second terminal 430. The second land pattern 432 may include a conductive portion 432a and a land portion 432b. The conductive portion 432a may have a substantial line shape. The conductive portion 432a may be electrically connected to the second terminal 430. The land portion 432b may be electrically connected to the conductive portion 432a. The land portion 432b may have a substantial plate shape.

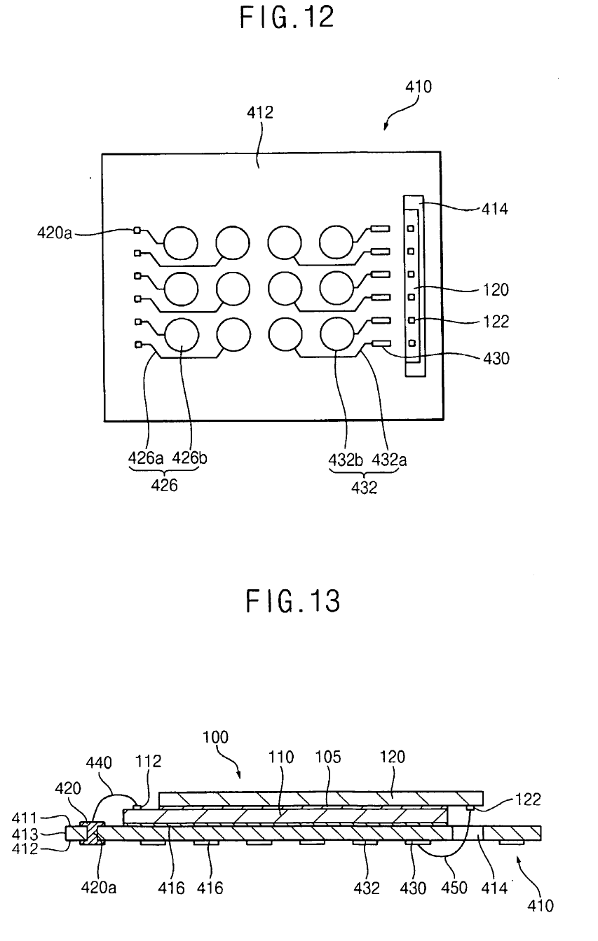

FIG. 13 is a cross-sectional view illustrating a conductive member assembling a signal input/output member 410 and a semiconductor chip assembly 100 in FIG. 10.

Referring to FIG. 13, the first pads 112 of the first semiconductor chip 110 included in the semiconductor chip assembly 100 provided on a first face 411 of a signal input/output member 410 may be electrically connected to the first terminals 420 protruding from the first face 411 of the signal input/output member 410. A first conductive wire 440 may electrically connect the first pads 112 to the first terminals 420.

The second pads 122 of the second semiconductor chip 120 included in the semiconductor chip assembly may be electrically connected to second terminals 430 protruding from a second face 412 of the signal input/output member 410. A second conductive wire 450 may connect the second pad 122 to the second terminal 430 through an opening 414 formed through the signal input/output member 410.

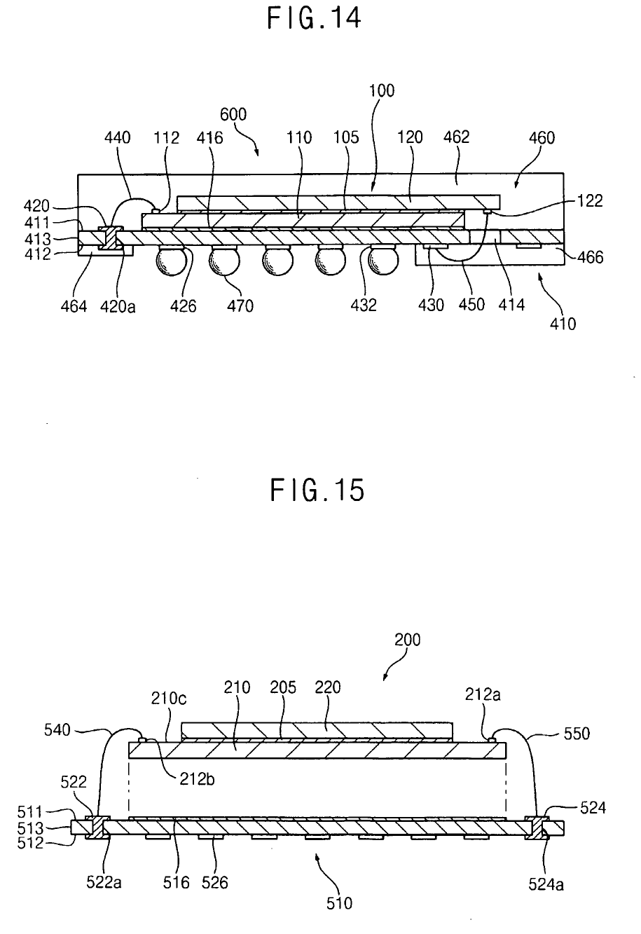

FIG. 14 is a cross-sectional view illustrating a semiconductor package 600 in accordance with an example embodiment.

Referring to FIG. 14, an encapsulating member 460 may include a first encapsulating member 462, a second encapsulating member 464 and a third encapsulating member 466.

The first encapsulating member 462 may be formed on a first face 411 of the signal input/output member 410 to cover the semiconductor chip assembly 100 and the first conductive wire 440. The first encapsulating member 462 may include epoxy resin, for example.

A second encapsulating member 464 may be provided on a second face 412 of the signal input/output member 410. The second encapsulating member 464 may cover the via pattern 420a electrically connected to the first terminal 420 on the first face 411. The second encapsulating member 464 may include epoxy resin, for example.

The third encapsulating member 466 may be provided on the second face 412 of the signal input/output member 410. The third encapsulating member 466 may cover the second terminal 430 protruding from the second face 412 and the second conductive wire 450. The third encapsulating member 466 may include epoxy resin, for example.

Conductive members 470 may be provided on a first land pattern 426 and a second land pattern 432 provided on the second face 412 of the signal input/output member 410.

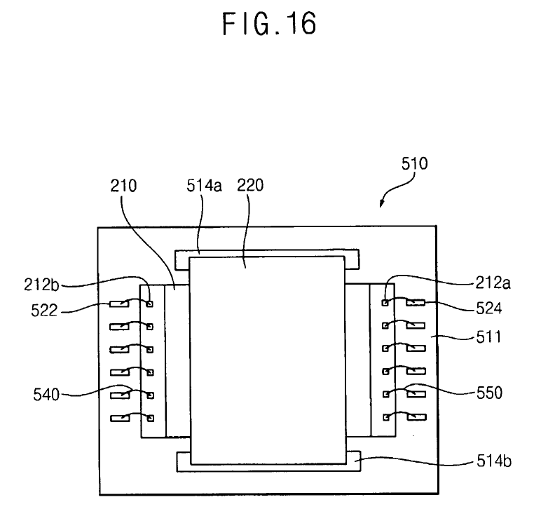

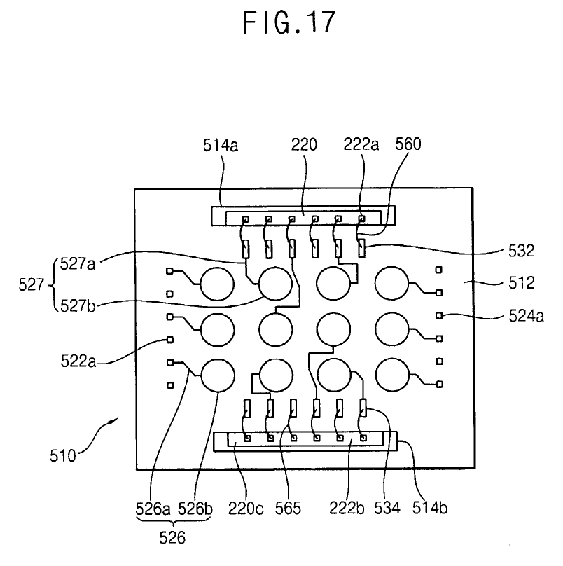

FIG. 15 is a cross-sectional view illustrating a semiconductor chip assembly 200 and a signal input/output member 510 of a semiconductor package in accordance with an example embodiment. FIG. 16 is a plan view illustrating a first face 511 of the signal input/output member 510 in FIG. 15. FIG. 17 is a plan view illustrating a second face 512 of the signal input/output member 510 in FIG. 15.

Referring to FIGS. 15 to 17, a semiconductor chip assembly 200 of a semiconductor chip package may include a first semiconductor chip 210 and a second semiconductor chip 220.

The first semiconductor chip 210 may include first pads 212a and 212b. The first pads 212a and 212b may be arranged along both edges of an active face 210c of the first semiconductor chip 210. By way of example only, the first pads 212a and 212b may be arranged in a substantial line shape. Alternatively, the first pads 212a and 212b may be arranged in a substantial zigzag shape, or some other alternative shape.

Referring to FIG. 17, the second semiconductor chip 220 may include second pads 222a and 222b. The second pads 222a and 222b may be arranged along both edges of an active face 220c of the second semiconductor chip 220. By way of example only, the second pads 222a and 222b may be arranged in a substantial line shape. Alternatively, the second pads 222a and 222b may be arranged in a substantial zigzag shape, or some other alternative shape.

An adhesion member 205 may be provided between the active face 210c of the first semiconductor chip 210 and the active face 220c of the second semiconductor chip 220. The adhesion member 205 may attach the second semiconductor chip 220 to the first semiconductor chip 210. Here, the first pads 212a and 212b of the first semiconductor chip 210 may not be overlapped with the second semiconductor chip 220. Thus, the first pads 212a and 212b protruding in a first direction may be exposed from the second semiconductor chip 220. In addition, the second pads 222a and 222b protruding in a second direction substantially opposite to the first direction may be exposed from the first semiconductor chip 210.

By way of example only, the first pads 212a and 212b may be arranged substantially perpendicular to the second pads 222a and 222b.

As described above, the active face 210c of the first semiconductor chip 210 and the active face 220c of the second semiconductor chip 220 may face each other. Thus, the active faces of the first and second semiconductor chips 210 and 220 may be protected from thermal and/or mechanical damage during manufacture of the semiconductor package. For example, the active faces 210c and 220c may be shielded from scratches that may otherwise occur when the semiconductor package is manufactured.

The signal input/output member 510 (see FIG. 15) may have a quadrilateral plate shape, for example. The signal input/output member 510 may include a first face 511, a second face 512, a side face 513 and two openings 514a and 514b. The second face 512 may be substantially opposite to the first face 511. The side face 513 may be connected between the first face 511 and the second face 512. The openings 514a and 514b (See FIG. 16) may be formed through the signal input/output member 510.

A semiconductor chip assembly 200 (see FIG. 15) may be provided on the first face 511. A first semiconductor chip 210 of the semiconductor chip assembly 200 may be provided on the first face 511. The first semiconductor chip 210 may be combined with the first face 511 by the adhesion member 516.

First terminals 522 and 524 (see FIG. 15) may be arranged at both edges of the first face 511. The first terminals 522 and 524 may correspond to the first pads 212a and 212b on the first semiconductor chip 210. The number of the first terminals 522 and 524 may be identical to that of the first pads 212a and 212b. In alternative embodiments, the number of the first terminals 522 and 524 may be different than the number of the first pads 212a and 212b.

The first terminals 522 and 524 formed at the first face 511 may extend to the second face 512 by via patterns 522a and 524a.

Referring to FIG. 17, second pads 222a and 222b provided on the second semiconductor chip 220 may correspond to the openings 514a and 514b formed through the signal input/output member 510, respectively.

Second terminals 532 and 534 (see FIG. 17) may be formed on the second face 512 of the signal input/output member 510. The second terminals 532 and 534 may correspond to the second pads 222a and 222b exposed by the openings 514a and 514b. The number of the second terminals 532 and 534 may be identical to that of the second pads 222a and 222b. In alternative embodiments, the number of the second terminals 532 and 534 may be different than the number of the second pads 222a and 222b.

Referring to FIG. 17, the signal input/output member 510 may include a first land pattern 526 and a second land pattern 527. The first land pattern 526 and second land pattern 527 may be formed on the second face 512.

The first land pattern 526 may be electrically connected to the first terminals 212a and 212b through the via patterns 522a and 524a. The first land pattern 526 may include a conductive portion 526a and a land portion 526b. The conductive portion 526a may have a substantial line shape. The conductive portion 526a may make electric contact with the via pattern 522a and 522b. The land portion 526b may be electrically connected to the conductive portion 526a. The land portion 526b may have a substantial plate shape.

The second land pattern 527 may be electrically connected to the second terminals 532 and 534. The second land pattern 527 may include a conductive portion 527a and a land portion 527b. The conductive portion 527a may have a substantial line shape. The conductive portion 527a may make electric contact with the second terminals 532 and 534. The land portion 527b may be electrically connected to the conductive portion 527a. The land portion 527b may have a substantial plate shape.

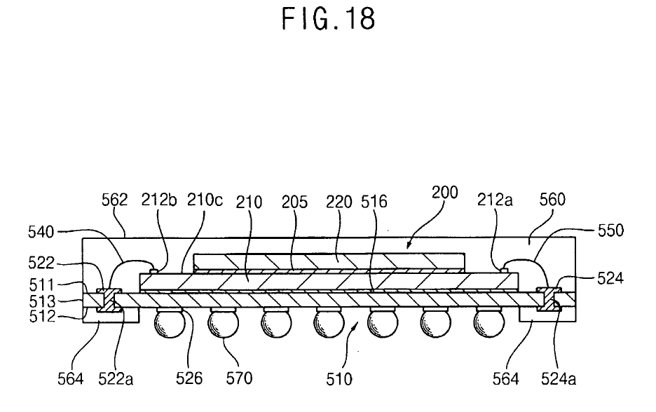

FIG. 18 is a cross-sectional view illustrating a semiconductor package in accordance with an example embodiment.

Referring to FIG. 18, the first pads 212a and 212b of the first semiconductor chip 210 provided on the first face 511 of the signal input/output member 510 may be electrically connected to the first terminals 522 and 524 provided on the first face 511 of the signal input/output member 510. The first pads 212a and 212b and the first terminals 522 and 524 may be electrically connected to each other by conductive wires 540 and 550.

The second pads 222a and 222b of the second semiconductor chip 220 of the semiconductor chip assembly 200 provided on the first face 511 of the signal input/output member 510 may be electrically connected to the second terminals 532 and 534 provided on the second face 512 of the signal input/output member 510. The second pads 222a and 222b may be connected to the second terminals 532 and 534 by second conductive wires 560 and 565 (see FIG. 17). The second conductive wires 560 and 565 may be formed through the openings 514a and 514b formed through the signal input/output member 510.

An encapsulating member 560 may include a first encapsulating member 562, a second encapsulating member 564 and a third encapsulating member 566 (not shown).

The first encapsulating member 562 may be provided on a first face 511 of the signal input/output member 510. The first encapsulating member 562 may cover the semiconductor chip assembly 200 and the first conductive wires 540 and 550. The first encapsulating member 562 may include epoxy resin, for example.

The second encapsulating member 564 may be provided on a second face 512 of the signal input/output member 510. The second encapsulating member 564 may cover the via patterns 522a and 524a electrically connected to the first terminals 522 and 524 formed on the first face 511. The second encapsulating member 564 may include epoxy resin, for example.

The third encapsulating member 566 may be provided on a second face 512 of the signal input/output member 510. The third encapsulating member 566 may cover the second terminals 532 and 534 and the second conductive wires 560 and 565. The third encapsulating member 566 may include epoxy resin, for example.

A conductive member 570 may be provided on the first land pattern 526 and the second land pattern 527 formed on the second face 512 of the signal input/output member 510.

As described above, an active face 210c of a first semiconductor chip 210 from which first pads 212a and 212b protrude may face an active face 220c of a second semiconductor chip 220 from which a second pads 222a and 222b protrude. In this way, the active faces of the first and second semiconductor chips may be protected from thermal and/or mechanical damaged in manufacturing the semiconductor package. For example, scratches in the active faces may be avoided during manufacture of the semiconductor package.

The foregoing is illustrative of example embodiments and is not to be construed as limiting thereof. Although example embodiments have been described, those skilled in the art will readily appreciate that many modifications are possible without materially departing from the teachings herein. Accordingly, all such modifications are intended to be included within the scope of the appended claims. It will be understood that the foregoing is illustrative of example embodiments and is not to be construed as limiting the example embodiment, and that modifications to example embodiments, as well as other embodiments, are intended to be included within the scope of the appended claims.

What is claimed is:

1. A semiconductor package comprising:
a semiconductor chip assembly having first pads and second pads, the first pads being exposed in a first direction, the second pads being exposed in a second direction opposite to the first direction;
a signal input/output member having first terminals and second terminals, the first terminals being electrically connected to the first pads, the second terminals being electrically connected to the second pads; and
an encapsulating member encapsulating the semiconductor chip assembly.

2. The semiconductor package of claim 1, wherein the semiconductor chip assembly includes a first semiconductor chip having the first pads and a second semiconductor chip having the second pads.

3. The semiconductor package of claim 2, wherein the semiconductor chip assembly includes an adhesion member attaching the second semiconductor chip to the first semiconductor chip.

4. The semiconductor package of claim 2, wherein the first pads are arranged at an edge of the first semiconductor chip, and
the second pads are arranged at an edge of the second semiconductor chip substantially opposite to the edge of the first semiconductor chip where the first pads are arranged.

5. The semiconductor package of claim 4, wherein the first pads are arranged in a substantial line shape and the second pads are arranged in a substantial line shape, the first pads and the second pads being arranged substantially in parallel with each other.

6. The semiconductor package of claim 2, wherein the first pads are arranged along two edges of the first semiconductor chip and the second pads are arranged along two edges of the second semiconductor chip.

7. The semiconductor package of claim 6, wherein the first pads are arranged in a substantial line shape, the second pads are arranged in a substantial line shape, and the first pads and the second pads are arranged substantially perpendicular to each other.

8. The semiconductor package of claim 1, wherein the signal input/output member includes a first die pad, a second die pad, first leads and second leads,
the first die pad being attached to a first face of the first semiconductor chip where the first pads are formed,
the second die pad being attached to a second face of the second semiconductor chip where the second pads are formed,
the first leads having the first terminals connected to the first pads, and
the second leads having the second terminals connected to the second pads.

9. The semiconductor package of claim 1, wherein the signal input/output member includes a substrate with a first face and a second face,
the first face supporting the first terminals,
the second face facing away from the first face, the second face supporting the second terminals, and
the substrate having an opening exposing the second pads.

10. The semiconductor package of claim 9, further comprising:
a first land pattern electrically connected to the first terminals; and
a second land pattern electrically connected to the second terminals.

11. The semiconductor package of claim 10, further comprising conductive bumps formed on the first land pattern and the second land pattern.

12. The semiconductor package of claim 11, wherein the conductive bump is a solder ball having a substantial spherical shape.

13. The semiconductor package of claim 1, further comprising first conductive wires electrically connecting the first terminals to the first pads and second conductive wires electrically connecting the second terminals to the second pads.
